(19) United States
(12) Patent Application Publication
(10) Pub. No.: US 2010/0328856 A1
(43) Pub. Date: Dec. 30, 2010

(54) ELECTRONIC DEVICE WITH MOVABLE HOUSING PARTS

(75) Inventors: Mika Ojanto, Salo (FI); Kimmo Komppa, Salo (FI); Pasi Kemppinen, Tampere (FI)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/527,491

(22) PCT Filed: Feb. 23, 2007
(86) PCT No.: PCT/EP07/01602

§ 371 Date: Sep. 14, 2010

(51) Int. Cl. H05K 7/00

(52) U.S. Cl. 361/679.01

(57) ABSTRACT

A mobile electronic device comprises a housing with a first housing part, a second housing part and a third housing part. The first and second housing parts are mounted for a slidable movement relative to one another, whilst the third housing part is mounted for pivotable movement relative to the second housing part. It is suggested that FIG. 4 is published with the abstract.

### FIELD OF THE INVENTION

The present invention relates to mobile electronic devices that include a housing having parts that are movable relative to one another, in particular to mobile electronic devices that have slideable housing parts that are movable relative to one another to conceal and unconceal a portion of an operating face.

### BACKGROUND OF THE INVENTION

Various models of slider phones as mobile phones with two slidably suspended housing parts are commonly referred are known. Common is that the sliding operation serves to conceal and unconceal a portion of the operating face. The slider phones are popular, but just like the candy bar models they have the disadvantage that the display screen is not directed at the user when the phone is placed flat on a table top. This drawback is aggravated when making video calls since the camera for video calls typically lies in the same surface as the display screen and the receiving party will see the ceiling or the sky and not the calling party.

### DISCLOSURE OF THE INVENTION

On this background, it is an object of the present invention to provide an electronic device overcomes or at least reduces the drawbacks described above.

This object is achieved by providing a mobile electronic device comprising a housing having at least a first housing part and a second housing part, the second housing part being mounted for slidable movement relative to the first housing part between an extended position and a retracted position, a third housing part connected to the second housing part, the third housing part being operably connected to the first and/or second housing part so that the third housing part makes a pivoting movement when the second housing part makes a sliding movement relative to the first housing part.

Thus, the third housing part is titled relative to the rest of the housing so that a display screen or camera on the third housing part will face a user when placed on a tabletop in front of the user.

The third housing part can be mounted for pivoting movement relative to the second housing part between an extended position and a retracted position.

The third housing part can be its retracted position when the second housing part is in its retracted position, and can be in its extended position when the second housing part is in its extended position.

The third housing part can include a portion of the operating face of the mobile electronic device, and the first housing part includes a portion of the operating face of the mobile electronic device.

The portion of the operating face on the third housing part can be substantially parallel to the operating face portion on the second and/or first housing part in the retracted position of the second and third housing parts.

The portion of the operating face on the third housing part can be at an angle with the operating face portion on the second and/or first housing part in the extended position of the second and third housing parts.

The operating face portion on the third housing part can include a display screen and/or a camera

The operating face portion on the second housing part can include a first portion of a keypad.

The operating face portion on the first housing part can include a second portion of a keypad.

The operating face portion on the first housing portion can include an alphanumerical keypad.

The alphanumeric keypad can be a UTI-T keypad

The operating face portion on the second housing part can include navigational user interface components.

The operating face portion on the second housing part can include one or more softkeys.

The third housing part can be operatively connected to the first housing part and the second housing part by a linkage mechanism.

The linkage mechanism can include a pair of tilt arms.

One extremity of each of the tilt arms can be guided by a track disposed in the first housing portion. The other extremity of the tilt arms can be connected to the third housing part.

The link arms can be pivotally connected to the second housing part in a position between the extremities.

The track can be formed by a guiding slot in which a peg attached to the extremity of the tilting arms is guided.

The track can include a portion that is substantially parallel with the operating face portion on the first housing part and a portion that is sloping away from the operating face portion on the first housing part.

The tilt arm can be pivotally connected at one point to a front side of the first housing portion and the tilt arm being pivotally connected at another point to a rear side of the third housing portion. The second housing part can be slidably mounted on the first housing part and the third housing part can at its lower edge be pivotally connected to and upper edge of the second housing part for pivoting about a pivot axis.

The pivot connection between the first housing part and said arm can be placed near an upper edge of said first housing part, preferably at a position that is below a plane in which said pivot axis second housing part makes a sliding movement when the second housing part makes a sliding movement relative to the first housing part. Further objects, features, advantages and properties of the mobile electronic device according to the invention will become apparent from the detailed description.

### BRIEF DESCRIPTION OF THE DRAWINGS

In the following detailed portion of the present description, the invention will be explained in more detail with reference to the exemplary embodiments shown in the drawings, in which:

FIG. 1 is a front-side and top view of the mobile electronic device according to the present invention in a retracted state,

FIG. 2 is a perspective view of the mobile electronic device shown in FIG. 1,

FIG. 3 is a front-side and top view of the mobile electronic device of FIG. 1 in an extended state,

FIG. 4 is a perspective view of the mobile electronic device shown in FIG. 3

FIG. 5 is a front-side and top view of a frame and linkage mechanism according to an embodiment of the invention in a retracted position,

FIG. 6 is a detailed side view of the linkage mechanism shown in FIG. 5,

FIG. 7 is a perspective view of the frame and linkage mechanism shown in FIG. 5,

FIG. 8 is a front-side and top view of a frame and linkage mechanism shown in FIG. 5 in an extended position,

FIG. 9 is a detailed side view of the linkage mechanism shown in FIG. 8,

FIG. 10 is a perspective view of the frame and linkage mechanism shown in FIG. 8,

FIG. 11 is an exploded view of the mobile electronic device shown in FIG. 1,

FIGS. 12 to 14 illustrate another embodiment of the mobile electronic device according to the invention by side views, and

FIGS. 15 to 18 illustrate yet another embodiment of the electronic device according to the invention by elevated views with detailed cutouts.

### DETAILED DESCRIPTION OF PREFERRED EMBODIMENTS

In the following detailed description, the keypad/touchpad according to the invention will be described in detail and as an implementation in a mobile device, e.g. a PDA, mobile terminal or a mobile communication terminal in detail in the form of a cellular/mobile phone by the preferred embodiments.

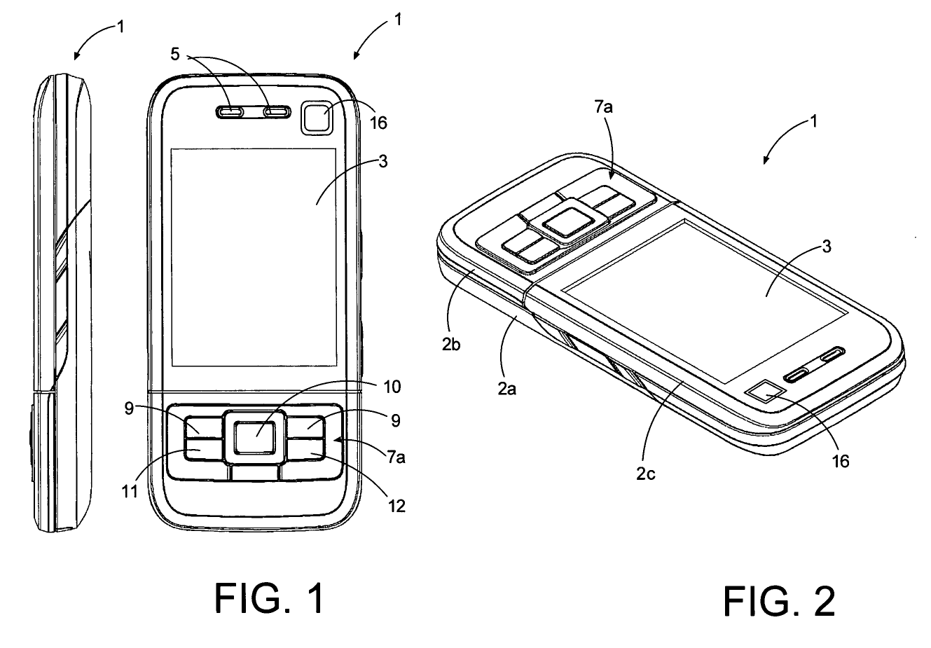

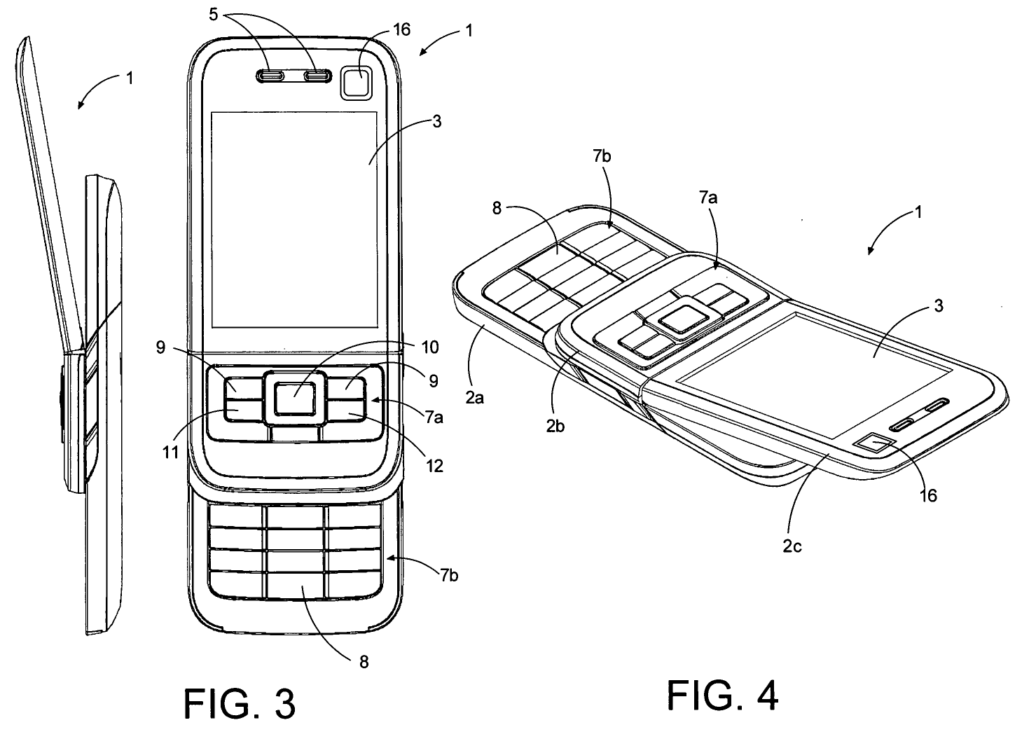

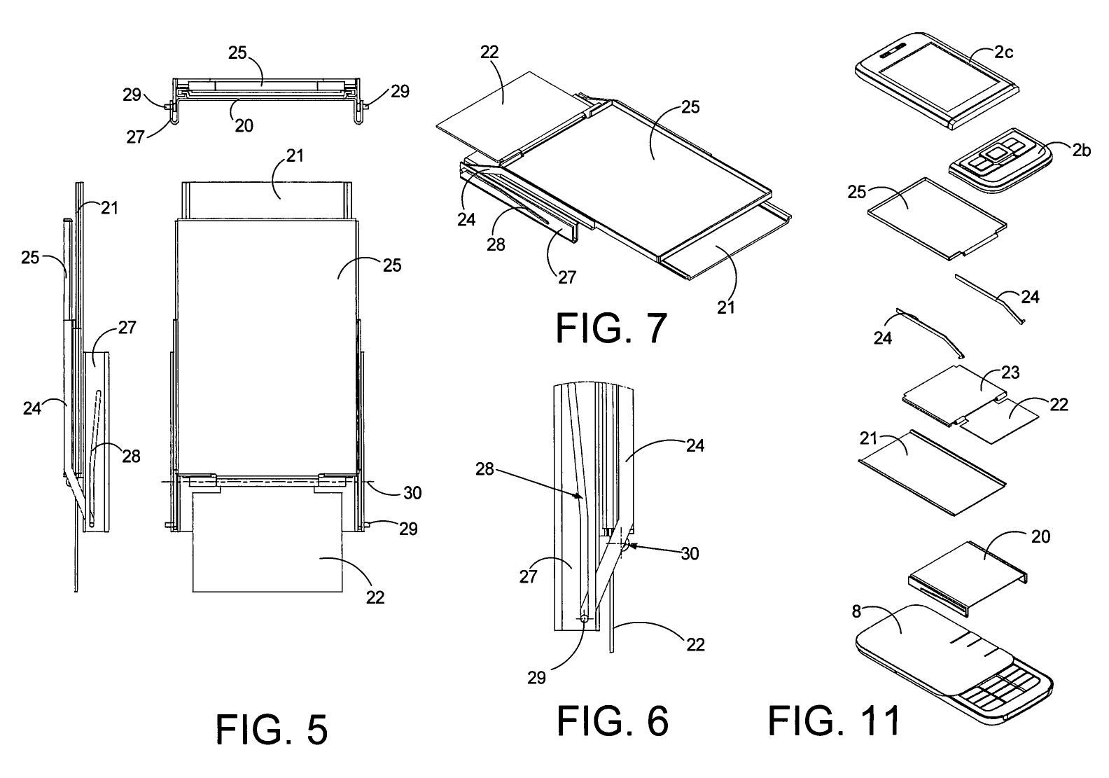

FIGS. 1 to 4 illustrate a first embodiment of a mobile device according to the invention in the form of a mobile telephone by a front view, a side view and a perspective view in a retracted position (FIGS. 1 and 2) and an extended position (FIGS. 3 and 4). The mobile phone 1 has a housing including housing part 2a, housing part 2b housing part 2c, a display screen 3, an on/off button (not shown), a speaker 5 (only the opening is shown), and a microphone (not visible in FIG. 1). The phone 1 according to the first preferred embodiment is adapted for communication via a cellular network, such as the GSM 900/1800 MHz network, but could just as well be adapted for use with a Code Division Multiple Access (CDMA) network, a 3G network, or a TCP/IP-based network to cover a possible VoIP-network (e.g. via WLAN, WIMAX or similar) or a mix of VoIP and Cellular such as UMA (Universal Mobile Access).

The operating face includes a keypad and the display screen 3. The keypad is divided in a first part 7a and a second part 7b. The second part 7b is disposed on the first housing part 2a and has a first group of keys 8 as alphanumeric keys, by means of which the user can enter a telephone number, write a text message (SMS), write a name (associated with the phone number), etc. Each of the twelve alphanumeric keys 8 is provided with a figure “0-9” or a sign “#” or “*”, respectively. In alpha mode each key is associated with a number of letters and special signs used in the text editing.

The second keypad part 7b includes a group of keys comprising two softkeys 9, two call handling keys (offhook key 11 and onhook key 12), and a 5-way navigation key 10 (up, down, left, right and center: select/activate). The function of the softkeys 9 depends on the state of the phone, and navigation in the menu is performed by using the navigation-key 10. The present function of the softkeys 9 is shown in separate fields (soft labels) in a dedicated area 4 of the display 3, just above the softkeys 9. The two call handling keys 11,12 are used for establishing a call or a conference call, terminating a call or rejecting an incoming call. This key layout is typical for many mobile phones, however, it is understood that completely different layout for the keypad and user interface can be used with different embodiments of the invention.

The navigation key 10 is a four- or five-way key which can be used for cursor movement, scrolling and selecting (five-way key) and is placed centrally on the front surface of the phone between the display 3 and the group of alphanumeric keys 7.

A releasable rear cover (not shown) gives access to the SIM card (not shown), and the battery pack (not shown) in the back of the phone that supplies electrical power for the electronic components of the mobile phone 1.

The mobile phone 1 has a flat display screen 3 that is typically made of an LCD with optional back lighting, such as a TFT matrix capable of displaying color images. A touch screen may be used on top of a conventional LCD display. A camera 16 for e.g. video calls is places on the right side just above the display screen 3.

The second housing part 2b is slidably connected to the first housing part 2a, and can assume a retracted position shown in FIGS. 1 and 2 and an extended position shown in FIGS. 3 and 4. In the retracted position shown in FIGS. 1 and 2 the second housing part 2b conceals the second keypad part 7b. In the retracted position in the third housing part 2c is substantially aligned with the first housing part and in close contact there with.

In the extended position shown in FIGS. 3 and 4 the second keypad part 7b is not concealed and the third housing part is tilted away from the first housing part 2a and forms a sharp angle with the first housing part. The angle between the third housing part 2c and the first housing part 2a in the extended position may vary and is in an embodiment between approximately 15 and 45°.

In use, the user slides the second housing part 2b towards the extended position in order to get access to the alphanumeric keypad 7b, or in order to answer a call or for using the mobile phone on a tabletop with the display and/or camera angled towards the user.

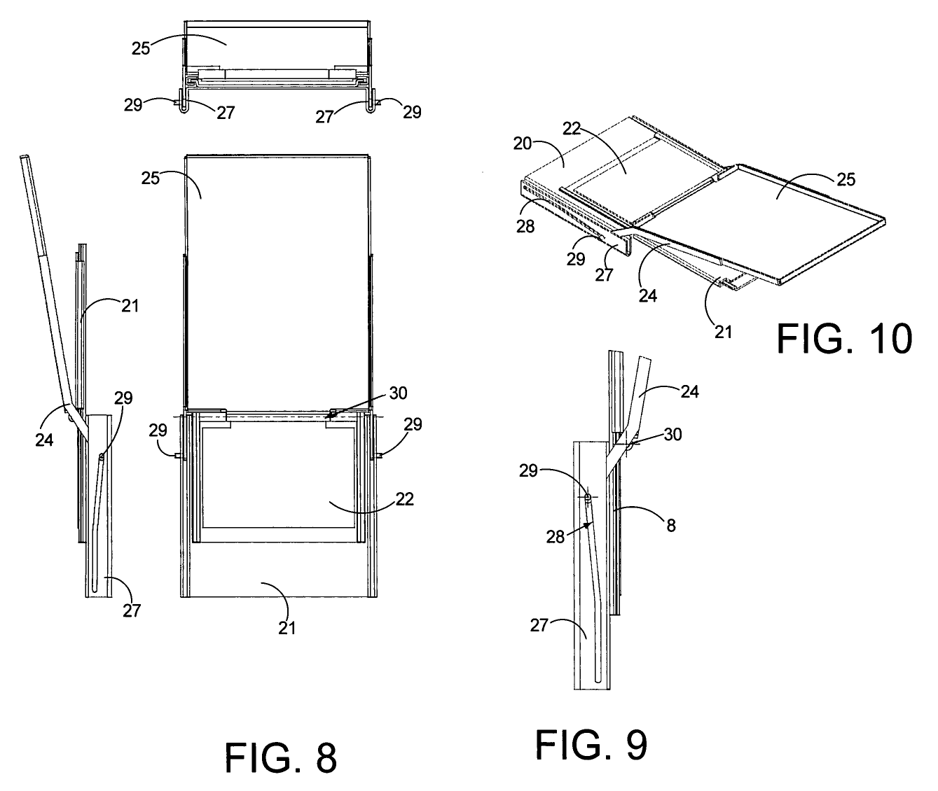

The linkage mechanism that causes the third housing part 2c (also called display block) to tilt in unison with the sliding movement of the second housing part 2b (also called function key block) will now be described with reference to FIGS. 5 to 10.

The linkage mechanism and frame of the mobile phone includes an LCD frame 25 to which the display block 2c is attached. The LCD frame 25 is carried by two tilt arms 24, a left and a right tilt arm. The function key block 2b is mounted on a divided slider 22,23. The LCD frame 25 is connected to the divided slider by a hinge with a pivot axis 30. The slider is guided by a slide base 21 by means of inwardly protecting guide rails in which the edges of the slide base 21 are guided. The slide base 21 is carried by a tilt base 20 that is secured to the first housing part 2a (also called Bolton block).

The proximate extremities of the tilt arms are provided with pegs 29 that are guided in a guiding slot 28 formed in downwardly projecting U-shaped ledges 27 of the tilt base. The guiding tracks 20 include a portion that is parallel with the sliding movement of the mobile phone and a portion that is angled away from the center of the mobile phone. Thus, in the retracted position in the guiding track 28 positions the pegs 29 close to the center of the mobile phone 1 and the building arms keep the display block 2c aligned with the mobile phone. In the retracted position the guiding track 28 positions the pegs 29 further away from the center of the mobile phone thereby tilting the display block 2c away from the bottom block 2a. Simultaneously, the display block 2c slides in unison with the function key block 2b.

The slider 23 slides along the slide rails of the slide base 21 and pushes LCD frame along the vertical axis. Simultaneously the proximate extremities of the tilt arms 24 are following the guiding slot in tilt base 20 forcing the LCD frame 25 to pivot around the hinge axis 30.

The tilt angle can be adjusted by shape, size and position of the tilt arms 25 and the guiding slots 28 in tilt base 22 as well as by the position of the hinge axis 30.

In an embodiment there can be only one tilt arm 24, disposed at a side of the mobile electronic device or in the middle of the mobile electronic device.

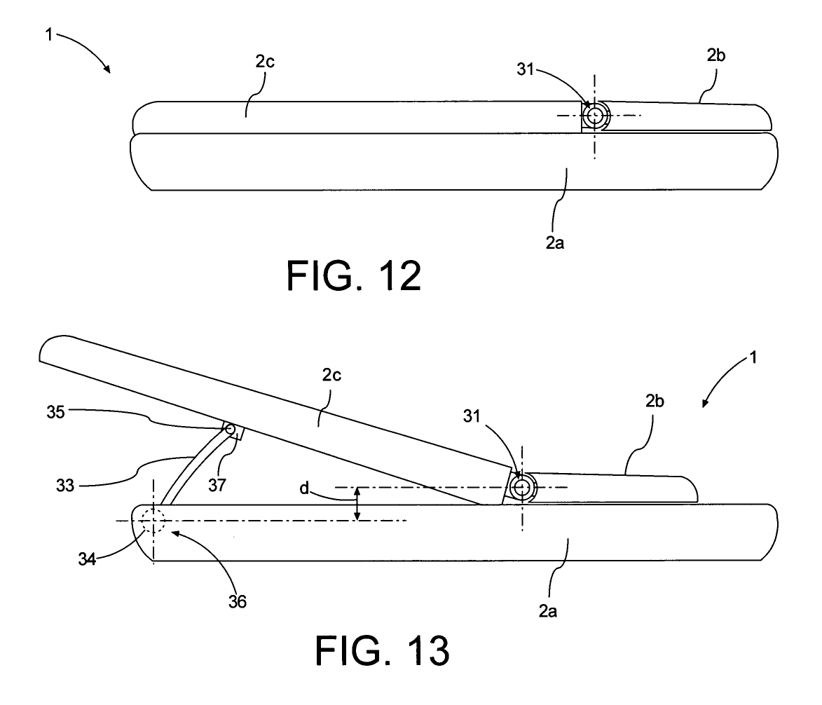

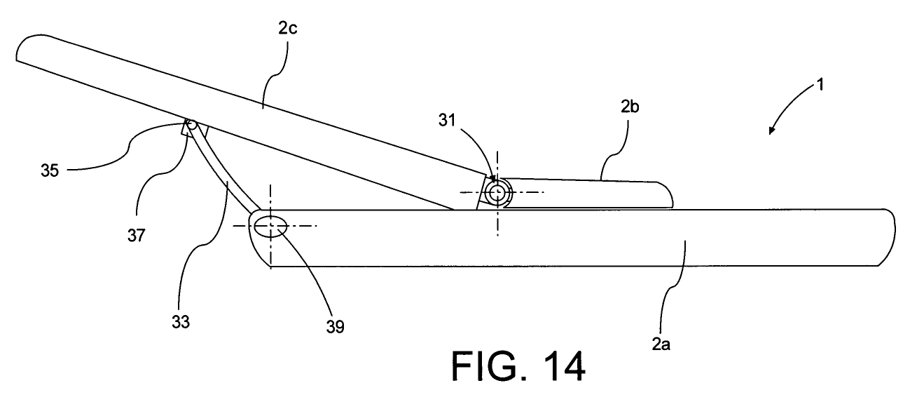

FIGS. 12 to 14 illustrate another embodiment of the mobile electronic device 1 according to the invention by side views. The front view of the mobile electronic device according to this embodiment is essentially identical with the front view of the mobile electronic device illustrated with a reference to FIGS. 1 to 4. The main difference between the embodiment of FIGS. 1 to 4 and the present embodiment is the mechanism that ensures that the third housing part 2c makes a tilting movement when the second housing part 2b makes a sliding movement. FIG. 12 illustrates the mobile electronic device 1 in the retracted position. FIG. 13 illustrates the mobile electronic device 1 in an intermediate position and FIG. 14 illustrates the mobile electronic device 1 in an extended position. The second housing part 2b is slidably connected to the first housing part 2a to be able to slide between the retracted and extended positions illustrated in the figures. The third housing part 2c is pivotally connected to the second housing part 2b by a hinge 31. The pivot axis of the hinge 31 is substantially parallel with the plane in which the second housing part slides (this could be a curved plane) and the pivot axis is substantially perpendicular to the sliding direction of the second housing part 2b. The third housing part 2c is connected to the first housing part 2a by a link arm 33. One end of the link arm 33 is pivotally connected to the rear of the second housing part 2c, via an attachment block 37 and a pivot pin 35. At its other end the link arm 33 is pivotally connected to the first housing part 2a. The pivot point to 36 of this connection is positioned near the upper edge of the first housing part, and below the pivot axis 31, which is illustrated by the distance d in FIG. 13. The distance d ensures that the link arm 33 will pivot in an upward direction when the second housing part 2b starts moving from the retracted position in the direction of the extended position. In an embodiment the link mechanism may be formed by a two link arms 33 that are disposed on opposite sides of the mobile electronic device 1, and these link arms 33 can be interconnected. Alternatively, only a single link arm 33 can be disposed substantially in the central part of the mobile electronic device 1.

In an embodiment the link arm or arms 33 maybe driven by a resilient actuator 34 that urges the link arm 33 in an anti-clockwise direction (anti-clockwise as in FIGS. 12-14). A pushbutton 39 at one or both sides of the first housing part 2a is used to trigger the opening movement under the influence of the resilient actuator 34. Thus, the opening movement from the retracted position to be in that position is automatic after pushing the button 39. The closing movement towards the retracted position has to be performed by the user against the force of the actuator 34.

In another embodiment, the actuator is of a resilient bi-stable type, and urges the second housing part 2b and the third housing part 2c towards the extended position from one side of a substantially intermediate position and urges the second housing part 2b and the third housing part 2c towards the retracted position from the other side of set substantially intermediate position. In this embodiment there is no need for any pushbutton to control the operation.

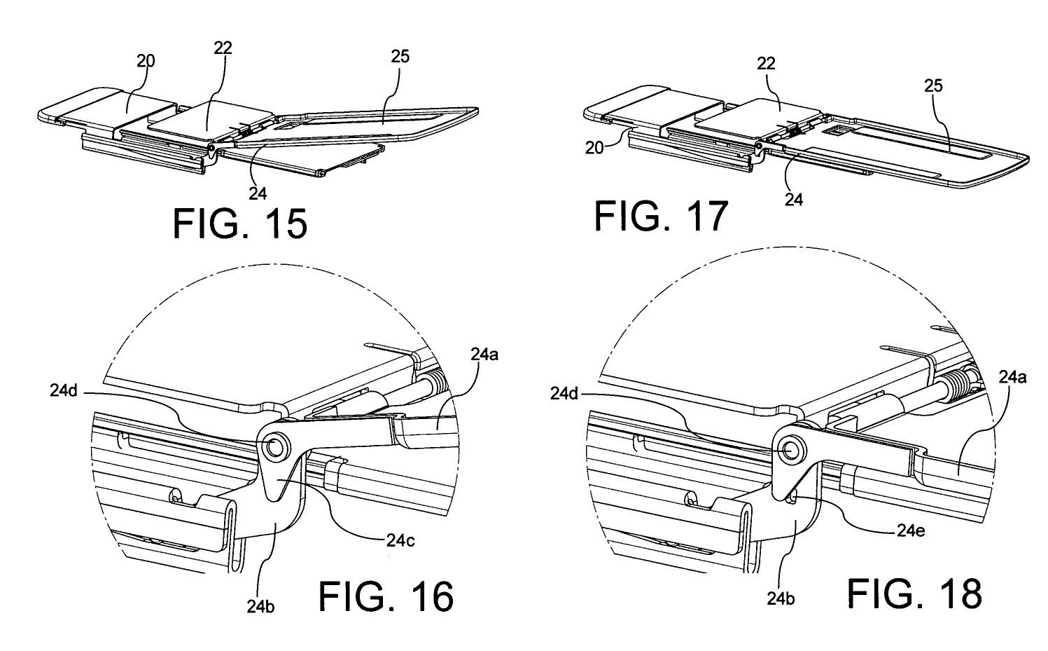

FIGS. 15 to 18 illustrate another embodiment of the electronic device according to the invention. This embodiment is essentially identical to the embodiments described above, except that the tilt arm 24 is collapsible. Hereto, the tilt arm 24 is divided into a proximate part 24b and a distal part 24a. The proximate part 24b and the distal part 24a are connected by a pivot 24d. The distal part 24a includes a lobe 24c that extends from the pivot 24d at an angle with the distal part 24a. The lobe 24c is provided with a protrusion (not visible in the drawings) that engages a recess 24e in the proximate part 24b. The lobe 24c and the proximate part 24b are pressed on to one another by the pivot 24d. Thus, force is required to disengage the protrusion from the recess 24e. When the protrusion disengages from the recess 24e the link arm 24 collapses and the LCD frame 25 can remain in a flat position even if the slider 22 is pushed towards the extended position. Thus, the collapsible link arm 24 forms an overload protection for the link mechanism.

The linkage mechanism and frame disclosed above are merely one ample of realizing in the invention, and many other slightly or completely different linkage mechanisms, electrical actuation systems or the like can readily be conceived to realize the tilting effect of the third housing part 2c during the sliding movement.

The invention has numerous advantages. Different embodiments or implementations may yield one or more of the following advantages. It should be noted that this is not an exhaustive list and there may be other advantages which are not described herein. One advantage of the invention is that it allows for the display screen of a slide type mobile electronic device to be seen properly by the user when placed in front of the user on a tabletop. Another advantage of the invention is that it allows for a camera of a slide type mobile electronic device to be directed properly at the user during a video call when placed in front of the user on a tabletop.

The term “comprising” as used in the claims does not exclude other elements or steps. The term “a” or “an” as used in the claims does not exclude a plurality.

The reference signs used in the claims shall not be construed as limiting the scope.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon. Moreover, it should be appreciated that those skilled in the art, upon consideration of the present disclosure, may make modifications and/or improvements on the apparatus hereof and yet remain within the scope and spirit hereof as set forth in the following claims.

1. A mobile electronic device comprising:
a housing having at least a first housing part and a second housing part,
said second housing part being mounted for slidable movement relative to the first housing part between an extended position and a retracted position,
a third housing part connected to the second housing part,
said third housing part being operably connected to said first and/or second housing part so that the third housing part makes a pivoting movement when said second housing part makes a sliding movement relative to said first housing part.

2. A mobile electronic device according to claim 1, wherein the third housing part is mounted for pivoting movement relative to the second housing part between an extended position and a retracted position.

3. A mobile electronic device according to claim 2, wherein said third housing part in its retracted position when the second housing part is in its retracted position, and wherein the third housing part in its extended position when the second housing part is in its extended position.

4. A mobile electronic device according to claim 3, wherein said third housing part includes a portion of the operating face of the mobile electronic device, and said first housing part includes a portion of the operating face of the mobile electronic device.

5. A mobile electronic device according to claim 4, wherein the portion of the operating face on the third housing part is substantially parallel to the operating face portion on the second and/or first housing part in the retracted position of the second and third housing parts.

6. A mobile electronic device according to claim 5, wherein the portion of the operating face on the third housing part is at an angle with the operating face portion on the second and/or first housing part in the extended position of the second and third housing parts.

7-23. (canceled)

24. A mobile electronic device according to claim 4, wherein the operating face portion on the third housing part includes a display screen and/or a camera.

25. A mobile electronic device according to claim 4, wherein the operating face portion on the second housing part includes a first portion of a keypad.

26. A mobile electronic device according to claim 4, wherein the operating face portion on the first housing part includes a second portion of a keypad.

27. A mobile electronic device according to claim 1, wherein said third housing part is operatively connected to said first housing part and said second housing part by a linkage mechanism.

28. A mobile electronic device according claim 27, wherein the linkage mechanism includes one tilt arm or a pair of tilt arms.

29. A mobile electronic device according to claim 28, wherein one extremity of each of said tilt arms is guided by a track disposed in the first housing portion.

30. A mobile electronic device according to claim 29, wherein the other extremity of said tilt arms is connected to said third housing part.

31. A mobile device according to claim 30, wherein said link arms are pivotally connected to said second housing part in a position between said extremities.

32. A mobile electronic device according to claim 29, wherein said track is formed by a guiding slot in which a peg attached to the extremity of the tilting arms is guided.

33. A mobile electronic device according to claim 29, wherein said track includes a portion that is substantially parallel with the operating face portion on said first housing part and a portion that is sloping away from said operating face portion on said first housing part.

34. A mobile electronic device according to claim 29, wherein said tilt arm is pivotally connected at one point to a front side of the first housing portion and the tilt arm being pivotally connected at another point to a rear side of the third housing portion.

35. A mobile electronic device according to claim 34, wherein the second housing part is slidably mounted on the first housing part and the third housing part is at its lower edge pivotally connected to and upper edge of the second housing part for pivoting about a pivot axis.

36. A mobile electronic device according to claim 35, wherein the pivot connection between the first housing part and said arm is near an upper edge of said first housing part, preferably at a position that is below a plane in which said pivot axis second housing part makes a sliding movement when the second housing part makes a sliding movement relative to the first housing part.
